(19) United States
(12) Patent Application Publication
(10) Pub. No.: US 2025/0220999 A1
(43) Pub. Date: Jul. 3, 2025

(54) LAMINATED STRUCTURE, METHOD FOR MANUFACTURING LAMINATED STRUCTURE, AND SEMICONDUCTOR DEVICE

(71) Applicant: Japan Display Inc., Tokyo (JP)

(72) Inventors: Hayata AOKI, Tokyo (JP); Masumi NISHIMURA, Tokyo (JP)

(73) Assignee: Japan Display Inc., Tokyo (JP)

(21) Appl. No.: 19/062,500

(22) Filed: Feb. 25, 2025

Related U.S. Application Data
(63) Continuation of application No. PCT/JP2023/030337, filed on Aug. 23, 2023.

(30) Foreign Application Priority Data
Sep. 1, 2022 (JP) 2022-139268

(51) Int. Cl. H10D 62/85; H01L 21/02; H10D 30/47; H10D 62/40; H10H 20/825

(52) U.S. Cl. CPC H10D 62/8503; H01L 21/02422; H01L 21/02488; H01L 21/0254; H01L 21/02609; H10D 62/405; H10D 30/471; H10H 20/825

(57) ABSTRACT

A laminated structure includes an amorphous substrate having an insulating surface, an orientation pattern on the amorphous substrate, an insulating layer in contact with a side surface of the orientation pattern and surrounding the periphery of the orientation pattern, and a semiconductor pattern containing gallium nitride on the orientation pattern, wherein the insulating layer has a first region overlapping the semiconductor pattern and a second region not overlapping the semiconductor pattern.

### CROSS-REFERENCE TO RELATED APPLICATIONS

This application is a Continuation of International Patent Application No. PCT/JP2023/030337, filed on Aug. 23, 2023, which claims the benefit of priority to Japanese Patent Application No. 2022-139268, filed on Sep. 1, 2022, the entire contents of which are incorporated herein by reference.

### FIELD

An embodiment of the present invention relates to a laminated structure containing gallium nitride formed on an amorphous substrate, a method for manufacturing the laminated structure, and a semiconductor device using the laminated structure.

### BACKGROUND

In recent years, a semiconductor device using a semiconductor layer (hereinafter referred to as “gallium nitride-based semiconductor layer”) containing gallium nitride (GaN) has been developed. For example, a transistor element such as a HEMT (High Electron Mobility Transistor) and a light-emitting element such as an LED (Light-emitting Diode) are known as a semiconductor device using the gallium nitride-based semiconductor layer. In particular, demand for a light-emitting device using the light-emitting diode (LED) for each pixel is high, and a technique for forming a highly crystalline gallium nitride-based semiconductor layer on a substrate other than a silicon substrate has been rapidly developed. For example, Japanese laid-open patent publication No. 2018-168029 discloses a technique in which a buffer layer is formed on an insulating substrate such as a sapphire substrate or a quartz glass substrate, an insulating pattern is formed on the buffer layer, and the gallium nitride-based semiconductor layer is formed on the buffer layer and the insulating pattern.

### SUMMARY

A laminated structure according to an embodiment of the present invention includes an amorphous substrate having an insulating surface, an orientation pattern on the amorphous substrate, an insulating layer in contact with a side surface of the orientation pattern and surrounding the periphery of the orientation pattern, and a semiconductor pattern containing gallium nitride on the orientation pattern, wherein the insulating layer has a first region overlapping the semiconductor pattern and a second region not overlapping the semiconductor pattern.

A laminated structure according to an embodiment of the present invention includes an amorphous substrate having an insulating surface, an orientation pattern on the amorphous substrate, an insulating layer in contact with an outer peripheral side surface of the orientation pattern and not contacting with the top surface of the orientation pattern, and a semiconductor pattern containing gallium nitride on the orientation pattern, wherein the orientation pattern has a first region overlapping the semiconductor pattern and a second region not overlapping the semiconductor pattern.

A method for manufacturing a laminated structure according to an embodiment of the present invention includes forming an orientation layer on an amorphous substrate having an insulating surface, forming an orientation pattern on the insulating surface by etching the orientation layer, depositing an insulating layer on the insulating surface and the orientation pattern, forming the insulating layer so as to contact with a side surface of the orientation pattern and to surround the periphery of the orientation pattern by etching the insulating layer, depositing a semiconductor layer containing gallium nitride on the insulating layer and the orientation pattern, and forming a semiconductor pattern on a top surface of the orientation pattern by etching the semiconductor layer containing gallium nitride, wherein the insulating layer surrounding the periphery of the orientation pattern has a first region overlapping the semiconductor pattern and a second region not overlapping the semiconductor pattern.

A method for manufacturing a laminated structure according to an embodiment of the present invention includes forming an orientation layer on an amorphous substrate having an insulating surface, forming an orientation pattern on the insulating surface by etching the orientation layer, depositing an insulating layer on the insulating surface and the orientation pattern, forming the insulating layer so as to contact with a side surface of the orientation pattern and to surround the periphery of the orientation pattern by etching the insulating layer, depositing a semiconductor layer containing gallium nitride on the insulating layer and the orientation pattern, and forming a semiconductor pattern on a top surface of the orientation pattern by etching the semiconductor layer containing gallium nitride, wherein the insulating layer surrounding the periphery of the orientation pattern has a first region overlapping the semiconductor pattern and a second region not overlapping the semiconductor pattern.

### BRIEF DESCRIPTION OF DRAWINGS

FIG. 1 is an end view showing a method for manufacturing a laminated structure according to an embodiment of the present invention.

FIG. 2 is an end view showing a method for manufacturing a laminated structure according to an embodiment of the present invention.

FIG. 3 is an end view showing a method for manufacturing a laminated structure according to an embodiment of the present invention.

FIG. 4 is an end view showing a method for manufacturing a laminated structure according to an embodiment of the present invention.

FIG. 5 is an end view showing a method for manufacturing a laminated structure according to an embodiment of the present invention.

FIG. 6 is an end view showing a method for manufacturing a laminated structure according to an embodiment of the present invention.

FIG. 7 is a plan view showing a laminated structure according to an embodiment of the present invention.

FIG. 8 is an end view showing a laminated structure according to an embodiment of the present invention.

FIG. 9 is an end view showing a laminated structure according to an embodiment of the present invention.

FIG. 10 is an end view showing a method for manufacturing a laminated structure according to an embodiment of the present invention.

FIG. 11 is an end view showing a semiconductor device using a laminated structure according to an embodiment of the present invention.

FIG. 12 is a plan view showing a light-emitting device using a semiconductor device using a laminated structure according to an embodiment of the present invention.

FIG. 13 is an end view showing a semiconductor device using a laminated structure according to an embodiment of the present invention.

### DESCRIPTION OF EMBODIMENTS

As in the above-described prior art, generally, a gallium nitride-based semiconductor layer is formed by epitaxial growth at a temperature exceeding 1000° C. using a sapphire substrate or a quartz glass substrate having a heat resistance of 1000° C. or higher. However, considering applications to a light-emitting display device, the use of an expensive sapphire substrate or quartz glass substrate is problematic in that it hinders the increase in the area of a display screen. In addition, in the processing at a temperature exceeding 1000° C., it takes time to raise the temperature at the start of the processing and to lower the temperature at the end of the processing, and the throughput decreases.

An embodiment of the present invention uses a highly crystalline gallium nitride-based semiconductor layer on an inexpensive amorphous substrate to form a laminated structure.

Hereinafter, embodiments of the present invention will be described with reference to the drawings and the like. However, the present invention can be implemented in various forms without departing from the gist thereof. The present invention is not to be construed as being limited to the description of the embodiments exemplified below. In the drawings, the widths, thicknesses, shapes, and the like of the respective portions may be schematically represented in comparison with actual embodiments for clarity of explanation. However, the drawings are merely examples, and do not limit the interpretation of the present invention.

In describing an embodiment of the present invention, a direction from a substrate toward a semiconductor layer is referred to as “on”, and a reverse direction thereof is referred to as “under”. However, the expression “on” or “under” merely describes the vertical relationship of each element. In addition, the expression “on” or “under” includes not only the case where a third element is interposed between a first element and a second element, but also the case where the third element is not interposed. Furthermore, the terms “on” or “under” include not only the case where the elements overlap in a plan view, but also the case where they do not overlap.

In describing the embodiments of the present invention, elements having the same functions as those described above may be denoted by the same reference signs or the same reference signs plus letters or other symbols, and descriptions thereof may be omitted. In addition, in the case where a part of an element needs to be described separately, a symbol such as a letter may be attached to a symbol indicating the element to distinguish the element. However, when it is not necessary to distinguish each part of the element, the description will be made using only the reference signs indicating the element.

In describing embodiments of the present invention, expressions such as “a includes A, B, or C,” “a includes any of A, B, and C,” and “a includes one selected from a group consisting of A, B, and C” do not exclude the case where a includes a plurality of combinations of A to C unless otherwise specified. Furthermore, these expressions do not exclude the case where a includes other elements.

### First Embodiment

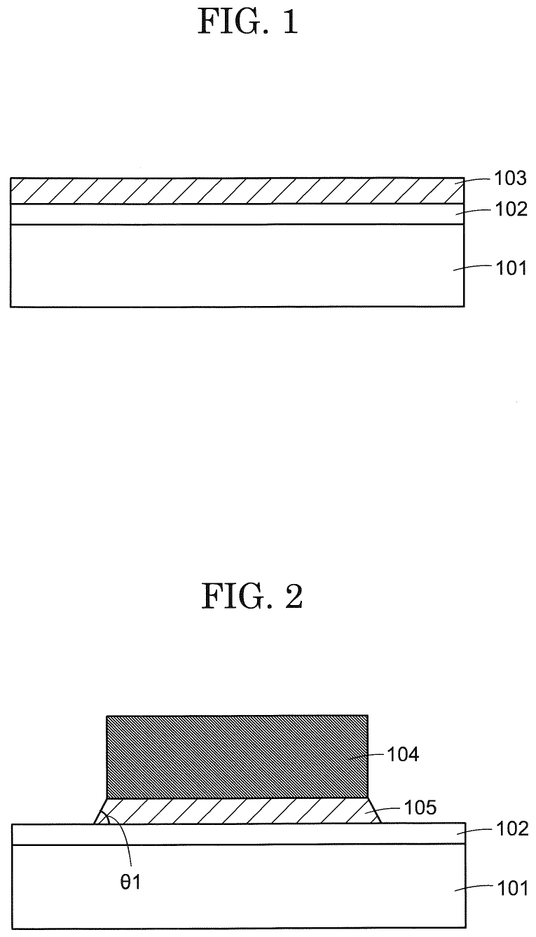

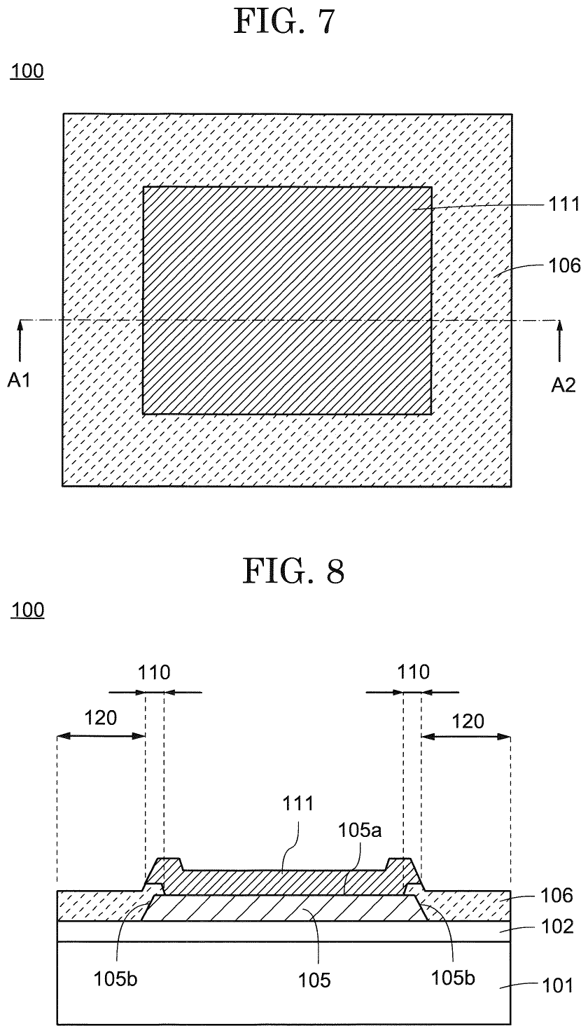

FIG. 1 to FIG. 8 are end views showing methods for manufacturing a laminated structure including a semiconductor pattern containing gallium nitride according to a first embodiment. In particular, FIG. 1 to FIG. 6 show examples of forming a semiconductive pattern containing gallium nitride on the amorphous substrate. FIG. 7 is a plan view of the laminated structure, and FIG. 8 is a cross-sectional view when the laminated structure shown in FIG. 7 is cut along a line A1-A2. In addition, although FIG. 1 to FIG. 8 show an example in which a single semiconductor pattern is formed, in practice, a plurality of semiconductor patterns is formed on the substrate.

First, as shown in FIG. 1, a base layer 102 is formed on an amorphous substrate 101. For example, a glass substrate can be used as the amorphous substrate 101. The glass substrate preferably has a low content of alkaline components, a low thermal expansion coefficient, a high strain point, and a high surface flatness. For example, the content of the alkali metal (such as sodium) is 0.1% or less, the thermal expansion coefficient is lower than 50×10⁻⁷/° C., and the strain point is preferably 600° C. or higher. As will be described later, in the present embodiment, since the gallium nitride-based semiconductor layer is formed by a sputtering method, a glass substrate having lower heat resistance than that of a sapphire substrate or quartz substrate can be used. Such a glass substrate is cheaper than a sapphire substrate and a quartz substrate, and is also suitable for increasing the area of the mother glass. However, the amorphous substrate 101 of the present embodiment is not limited to the glass substrate, and may be a resin substrate such as a polyimide substrate, an acryl substrate, a siloxane substrate, or a fluororesin substrate.

For example, in the case where gallium nitride is grown on the amorphous substrate 101, such as an amorphous glass, the crystallinity of gallium nitride is affected by the surface state of the amorphous substrate 101. In particular, unevenness on the surface of the amorphous substrate 101 is a factor that generates random crystalline nuclei. As a result, crystal growth of gallium nitride occurs in a random direction, and adjacent crystals interfere with each other, thereby inhibiting crystal growth. Therefore, the base layer 102 is arranged on the amorphous substrate 101. By arranging the base layer 102, the unevenness on the surface of the amorphous substrate 101 can be relieved. The material of the base layer 102 also affects the crystallinity of the subsequently formed gallium nitride.

The base layer 102 serves as a protective layer that prevents an impurity from entering from the amorphous substrate 101. For example, the base layer 102 is composed of one or more insulating layers selected from a silicon nitride layer, a silicon oxide layer, an aluminum nitride layer, and an aluminum oxide layer. In the present embodiment, the aluminum nitride layer is used as the base layer 102. In addition, a thickness of the base layer 102 is 5 nm or more and 50 nm or less. For example, the base layer 102 is formed by the sputtering method, a CVD method, a vacuum vapor deposition method, an electron beam evaporation method, or an ALD (Atomic Layer Deposition) method or the like. In order to increase the flatness of the base layer 102, a planarization process may be performed. For example, the planarization process refers to a reverse sputtering process or an etching process.

An orientation layer 103 is formed on the base layer 102. The orientation layer 103 has the function of improving the orientation of the crystal of a semiconductor layer 108 when forming the semiconductor layer 108 containing gallium nitride (see FIG. 2), which will be described later.

The orientation layer 103 may be conductive or insulating, but preferably has crystallinity oriented along a specific axis (for example, the c-axis). The orientation layer 103 is preferably a crystal having rotational symmetry. For example, the crystal surface preferably has six-fold rotational symmetry. In addition, the orientation layer 103 preferably has a hexagonal close-packed structure, a face-centered cubic structure, or a structure equivalent thereto. In this case, the structure equivalent to the hexagonal close-packed structure or the face-centered cubic structure includes a crystal structure in which the c-axis does not form 90 degrees with respect to the a-axis and the b-axis. The orientation layer 103 having the hexagonal close-packed structure or the structure equivalent thereto is preferably oriented in the (0001) direction, that is, the c-axis direction, with respect to the amorphous substrate 101. The orientation layer 103 having the face-centered cubic structure or the structure equivalent thereto is preferably oriented in the (111) direction with respect to the amorphous substrate 101.

For example, conductive orientation layers such as titanium (Ti), titanium nitride (TiNₓ), titanium oxide (TiOₓ), graphene, zinc oxide (ZnO), magnesium diboride (MgB₂), aluminum (Al), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), thorium (Th), and the like can be used as the orientation layer 103. In particular, titanium, graphene, and zinc oxide are preferably used as the orientation layer 103 having conductivity. In the present embodiment, a titanium layer is used as the orientation layer 103.

For example, insulating orientation layers such as aluminum nitride (AlN), aluminum oxide (Al₂O₃), lithium niobate (LiNbO), BiLaTiO, SrFeO, BiFeO, BaFeO, ZnFeO, PMnN-PZT, biological apatite (BAp), or the like can be used as the orientation layer 103. In particular, aluminum nitride or aluminum oxide is preferably used as the insulating orientation layer. In the present embodiment, the aluminum nitride layer is preferably used as the insulating orientation layer.

In this specification and the like, the orientation layer 103 may be a conductive orientation layer or an insulating orientation layer. In the case where there is no need to distinguish between the conductive orientation layer and the insulating orientation layer, the layer is expressed as the orientation layer 103.

The surface state of the orientation layer 103 affects the crystallinity of the semiconductor layer 108 described below. Therefore, the surface of the orientation layer 103 is preferably flat. For example, the orientation layer 103 preferably has a surface arithmetic mean roughness (Ra) of less than 2.3 nm. When the surface roughness of the orientation layer 103 is less than 2.3 nm, the semiconductor layer 108 having the c-axis orientation can be formed. Furthermore, in order to enhance the flatness of the orientation layer 103, the planarization process described in the base layer 102 may also be performed on the surface of the orientation layer 103 before forming the semiconductor layer 108.

In the present embodiment, the aluminum nitride layer is used as the base layer 102, and the titanium layer is used as the orientation layer 103. By using the aluminum nitride layer as the base layer 102, the flatness of the base layer 102 can be improved. In addition, the titanium layer is formed as the orientation layer 103 on the base layer 102 having a flat surface. As a result, the flatness of the orientation layer 103 can be improved. Therefore, it is preferable because it increases the crystallinity of the subsequently formed semiconductor layer 108.

For example, a thickness of the orientation layer 103 is 50 nm or more (preferably, 50 nm or more and 100 nm or less). The orientation layer 103 may be formed by any method. For example, the orientation layer 103 is formed by the sputtering method, the CVD method, the vacuum vapor deposition method, the electron beam evaporation method, or the ALD method.

Next, as shown in FIG. 2, a resist mask 104 is formed on the orientation layer 103, and the orientation layer 103 is etched using the resist mask to form an orientation pattern 105. Thereafter, the resist mask 104 is removed. The orientation pattern 105 has a gradient (hereinafter referred to as a “taper”) in which the angle of the side surface with respect to the bottom surface is θ1. By using a dry etching method for etching the orientation layer 103, the taper can be easily increased, and depending on the conditions, a taper angle θ1 of the orientation pattern 105 can be 60° or more. In addition, by using a wet etching method for etching the orientation layer 103, the taper angle θ1 of the orientation pattern 105 can be 20° or more and 50° or less (preferably, 30° or more and 40° or less). In the present embodiment, the orientation layer 103 is etched by the dry etching method, so the taper angle θ1 of the orientation pattern 105 is 60° or more.

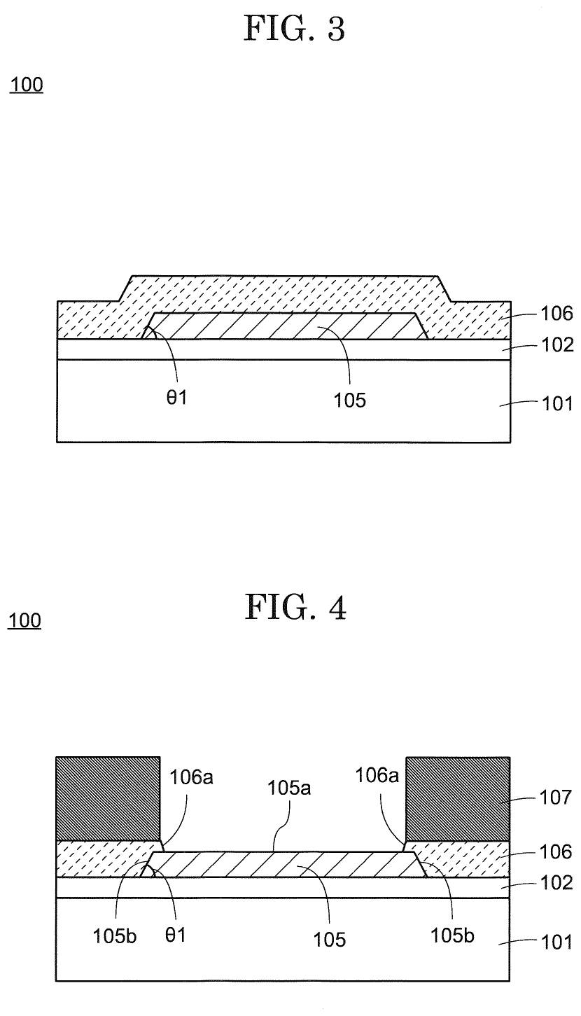

Next, as shown in FIG. 3, an insulating layer 106 is formed to cover the orientation pattern 105. An inorganic insulating material such as silicon oxide or silicon nitride is used as the insulating layer 106. In the present embodiment, silicon nitride is formed by the CVD method as the insulating layer 106. In the case where the insulating layer 106 is formed using the inorganic insulating material, the shape of the insulating layer 106 is a shape having unevenness reflecting the shape of the orientation pattern 105. In addition, in the case where the material of the base layer 102 and the material of the insulating layer 106 are the same, the sealing performance can be improved. Furthermore, in the case where the material of the base layer 102 is different from the material of the insulating layer 106, a material that does not affect the orientation pattern 105 may be selected.

Next, as shown in FIG. 4, a resist mask 107 is formed on the insulating layer 106, and the insulating layer 106 is etched using the resist mask 107 to form an opening 106a exposing a top surface 105a of the orientation pattern 105. As a result, the insulating layer 106 is shaped so as to be in contact with the orientation pattern 105 on a side surface 105b and surround the periphery of the orientation pattern 105. The periphery of the orientation pattern 105 is a portion including the side surface 105b and a part of the top surface 105a of the orientation pattern. In addition, a thickness of the insulating layer 106 is, for example, in a range of 50 nm or more and 100 nm or less. The thickness of the insulating layer 106 is preferably about the same as that of the orientation pattern 105. In addition, the thickness of the insulating layer 106 may be greater than a thickness of the orientation pattern 105, but is preferably not greater than twice the thickness of the orientation pattern 105. For example, if the thickness of the insulating layer 106 exceeds twice the thickness of the orientation pattern 105, a step is formed between the top surface 105a of the orientation pattern 105 and the top surface of the insulating layer 106. The step caused by the insulating layer 106 may reduce the crystallinity of a semiconductor layer formed later. In addition, when the thickness of the insulating layer 106 is less than the thickness of the orientation pattern 105, the insulating layer 106 on the orientation pattern 105 may disappear when the insulating layer 106 is etched. By making the thickness of the insulating layer 106 arranged on the orientation pattern 105 substantially the same thickness as the thickness of the orientation pattern, the side surface 105b of the orientation pattern 105 can be covered and the top surface 105a of the orientation pattern 105 can be protected. After the etching, the resist mask 107 is removed to obtain the orientation pattern 105.

The crystal orientation axis of the semiconductor layer 108 subsequently deposited is affected by the surface of the insulating layer 106 and the surface of the orientation pattern 105. Therefore, the surfaces of the insulating layer 106 and the orientation pattern preferably have a flat surface. For example, the thickness of the insulating layer 106 may be greater than the thickness of the orientation pattern 105, and a planarization process may be performed on the surface of the insulating layer 106 so that the surface of the orientation pattern 105 is not exposed before forming the resist mask 107. For example, a polishing treatment may be performed on the surface of the insulating layer 106. That is, in the insulating layer 106, a process may be performed in which the thickness of the region overlapping the orientation pattern 105 is made smaller than the thickness of the region not overlapping the orientation pattern 105. This makes it possible to form a flat surface with reduced unevenness on the surface of the insulating layer 106.

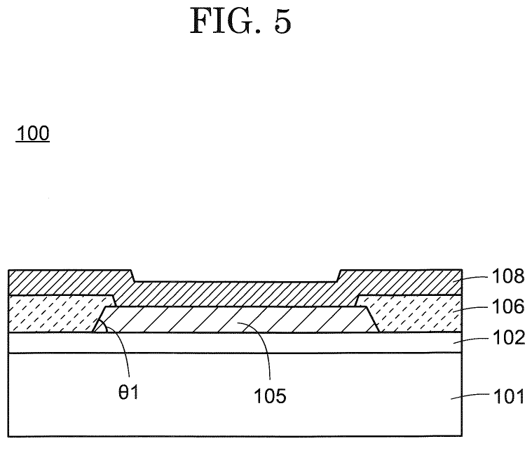

Next, as shown in FIG. 5, the semiconductor layer 108 is formed on the orientation pattern 105. In the present embodiment, gallium nitride is formed as the semiconductor layer 108 by the sputtering method. Specifically, for example, the gallium nitride is formed by the sputtering method in a state where the amorphous substrate 101 having an insulating surface (here, the amorphous substrate 101 in which the base layer 102 is arranged) is heated to 25° C. to 600° C., preferably 25° C. to 400° C. In other words, gallium nitride is formed at a temperature equal to or lower than the strain point of the amorphous substrate 101. Although gallium nitride is usually formed by a MOCVD method (Metal Organic Chemical Vapor Deposition), the MOCVD method is not appropriate in view of the heat resistance of the amorphous substrate 101 because the process temperature is high.

On the other hand, in the present embodiment, by using the sputtering method, the semiconductor layer 108 can be formed on the inexpensive amorphous substrate 101 at a lower temperature than using the MOCVD method. In addition, the semiconductor layer 108 is formed on the orientation pattern 105 having crystallinity oriented along a specific axis (for example, the c-axis). Furthermore, the base layer 102 relieves the surface unevenness of the amorphous substrate 101, thereby relieving the surface unevenness of the orientation pattern 105 formed on the base layer 102. As a result, the highly crystalline semiconductor layer 108 can be formed even when the semiconductor layer 108 is formed at a lower temperature than using the MOCVD method. In addition, since the amorphous substrate 101 can have a larger area than that of the sapphire substrate, it is possible to form a laminated structure 100 having a large area.

For example, the semiconductor layer 108 is formed by performing the sputtering using a sintered body of gallium nitride as a sputtering target and argon (Ar) or a mixed gas of argon (Ar) and nitrogen (N₂) as a sputtering gas. For example, a two-pole sputtering method, a magnetron sputtering method, a dual magnetron sputtering method, an opposing target sputtering method, an ion beam sputtering method, or an inductively coupled plasma (ICP) sputtering method can be applied as the sputtering method.

The conductivity type of the semiconductor layer 108 may be substantially intrinsic or may have n-type conductivity or p-type conductivity. The semiconductor layer 108 having n-type conductivity may not contain a dopant for performing valence electron control or may be doped with silicon (Si) or germanium (Ge) as an n-type dopant. The semiconductor layer 108 having p-type conductivity may be doped with one element selected from magnesium (Mg), zinc (Zn), cadmium (Cd), and beryllium (Be) as a p-type dopant. In the case where the n-type dopant is added to the semiconductor layer 108, the carrier concentration is preferably 1×10¹⁸/cm³ or more. In the case where the p-type dopant is added to the semiconductor layer 108, the carrier concentration is preferably 5×10¹⁶/cm³ or more. Furthermore, in the case where the semiconductor layer 108 is substantially intrinsic, zinc (Zn) may be contained as a dopant.

In addition, the semiconductor layer 108 may contain one or more elements selected from indium (In), aluminum (Al), and arsenic (As). A bandgap of the semiconductor layer 108 can be adjusted by these elements.

As described above, in the present embodiment, the semiconductor layer 108 containing gallium nitride is formed on the amorphous substrate 101 on which the orientation pattern 105 is formed. The crystallinity of the semiconductor layer 108 formed on the orientation pattern 105 is affected by the orientation axis of the orientation pattern 105. For example, in the case where the orientation pattern 105 has crystallinity of rotational symmetry or c-axis oriented crystallinity, the semiconductor layer 108 also has crystallinity of c-axis orientation or (111) orientation. The crystallinity of the semiconductor layer 108 is preferably monocrystalline, but may be polycrystalline, microcrystalline, or nanocrystalline. The crystal structure of the semiconductor layer 108 may have a wurtzite structure. The orientation of the semiconductor layer 108 is preferably the c-axis orientation or (111) orientation. The semiconductor layer 108 may contain an amorphous structure near the interface in contact with the orientation pattern 105, but preferably has crystallinity in bulk.

A thickness of the semiconductor layer 108 is 100 nm or more and 1 μm or less. However, the thickness of the semiconductor layer 108 is not limited, and may be appropriately set according to the structure of the device. The semiconductor layer 108 may have a single-layer structure, or may be a laminated structure including a plurality of layers having different conductivity types and/or compositions.

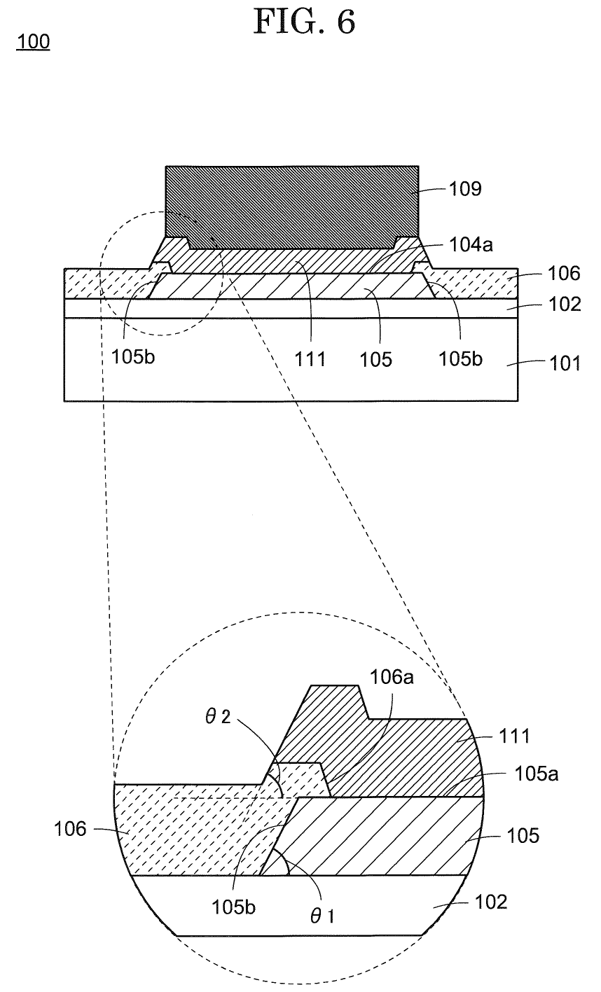

Next, as shown in FIG. 6, a resist mask 109 is formed on the semiconductor layer 108. Next, the semiconductor layer 108 is etched using the resist mask 109 to form a semiconductor pattern 111. In the present embodiment, the semiconductor layer 108 is etched by dry etching using a halogenated gas. The halogenated gas is not particularly limited as long as it contains at least one or more halogen atoms such as a chlorine atom, a fluorine atom, and a bromine atom and is in a gaseous state at room temperature, and examples thereof include CF₄, C₂F₆, C₃F₈, C₂F₄, C₄F₈, C₄F₆, C₅F₈, CHF₃, CCl₄, CClF₃, AlF₃, AlCl₃ and the like. In addition, a plurality of halogenated gases may be mixed and used. A chlorine-based gas such as CCl₄, CClF₃, AlF₃, or AlCl₃ is preferably used as the halogenated gas. Therefore, a taper angle θ2 of the semiconductor pattern 111 can be 60° or more. However, the present invention is not limited to this example, and the semiconductor pattern 111 may be formed using the wet etching method. As shown in FIG. 6, the semiconductor pattern 111 has a gradient (hereinafter referred to as “taper”) in which the angle of the side surface with respect to the bottom surface is θ2. Therefore, in the case where the wet etching method is used, the taper angle θ2 of the semiconductor pattern 111 can be 20° or more and 50° or less (preferably, 30° or more and 40° or less). After the etching, the resist mask 109 is removed to obtain the semiconductor pattern 111 containing gallium nitride.

In this case, the insulating layer 106 includes a first region 110 (see FIG. 8) that overlaps the semiconductor pattern 111, and a second region 120 (see FIG. 8) that does not overlap the semiconductor pattern 111. In addition, the top surface of the second region 120 in the insulating layer 106 is positioned below the top surface of the first region 110. In other words, in the insulating layer 106, the first region 110 is a region that overlaps the orientation pattern 105 and the second region 120 is a region that does not overlap the orientation pattern 105. In addition, in the insulating layer 106, the thickness of the second region 120 is larger than the thickness of the first region 110. Further, the insulating layer 106 has a side surface in the second region 120 that is contiguous with the top surface of the first region 110.

FIG. 7 is a plan view of the laminated structure 100 having the semiconductor pattern 111 containing gallium nitride. In addition, FIG. 8 is an end view of the laminated structure 100 when the laminated structure 100 is cut along a line A1-A2.

The laminated structure 100 according to the present embodiment includes forming the orientation layer 103 on the amorphous substrate 101 having the insulating surface, forming the orientation pattern 105 on the insulating surface by etching the orientation layer 103, depositing the insulating layer 106 on the insulating surface and the orientation pattern 105, forming the insulating layer 106 by etching so as to be in contact with the side surface 105b and to surround the periphery of the orientation pattern 105, depositing the semiconductor layer 108 containing gallium nitride on the insulating layer 106 and the orientation pattern 105, and forming the semiconductor pattern 111 on the top surface 105a of the orientation pattern 105 by etching the semiconductor layer 108 containing gallium nitride. In addition, the insulating layer 106 surrounding the periphery of the orientation pattern 105 has the first region 110 that overlaps the semiconductor pattern 111 and the second region 120 that does not overlap the semiconductor pattern 111.

The laminated structure 100 according to an embodiment of the present invention includes the highly crystalline semiconductor pattern 111 with the c-axis orientation. In addition, the laminated structure 100 includes the amorphous substrate 101 having an area which can be increased. Therefore, by utilizing the laminated structure 100, productivity of the LED containing gallium nitride can be increased, or a backplane in which a transistor containing gallium nitride is formed can be manufactured.

The semiconductor pattern 111 of the present embodiment has crystallinity aligned with a specific orientation axis reflecting the orientation of the orientation pattern 105 and the insulating layer 106. Therefore, by processing the semiconductor pattern 111 of the present embodiment and using it in the semiconductor device, it is possible to realize a semiconductor device with excellent characteristics.

In addition, by patterning the orientation layer 103 to form the orientation pattern 105, a high-definition semiconductor device can be formed as compared with the case where the orientation layer is not patterned. In addition, by using a conductive material as the orientation pattern 105, it is possible to use the orientation pattern 105 as a wiring and an electrode.

If the unevenness is formed by the insulating layer 106 when the semiconductor layer 108 is formed, the uneven shape may affect and reduce the crystallinity of the semiconductor layer 108. Therefore, in the insulating layer 106, a process of making the thickness of the first region 110 overlapping the orientation pattern 105 smaller than the thickness of the second region 120 not overlapping the orientation pattern 105 may be performed. By performing such a process, the uneven shape of the insulating layer 106 can be reduced when the semiconductor layer 108 is formed on the orientation pattern 105 and the insulating layer 106. Since the semiconductor layer 108 can be deposited on a surface that is as flat as possible, the crystallinity of the semiconductor layer 108 can be improved.

In the case where the dry etching method is used for etching the orientation layer 103, the taper angle θ1 of the orientation pattern 105 tends to be large, and the taper angle θ1 is 60° or more depending on the conditions. For example, in the case where the gallium nitride layer is deposited and the gallium nitride layer is etched immediately after the orientation pattern 105 is formed, an etching residue (a residue of the gallium nitride layer) may occur near the bottom end of the tapered portion (near the boundary between the base layer 102 and the orientation pattern 105). In the case where the high-definition semiconductor device is formed, the adjacent orientation patterns 105 are also in close proximity. Therefore, if a gallium nitride residue is generated, there is a risk that the residue may cause adjacent orientation patterns 105 to become conductive with each other.

In the present embodiment, the insulating layer 106 is arranged so as to surround the periphery of the orientation pattern 105. The semiconductor layer 108 is deposited on the orientation pattern 105 and the insulating layer 106 and etched on the insulating layer 106. Therefore, regardless of the taper angle θ1 of the orientation pattern 105, it is possible to suppress the occurrence of etching residue of the semiconductor layer 108 near the bottom end of the tapered portion of the orientation pattern 105. As a result, conduction caused by the etching residue can be suppressed.

### Second Embodiment

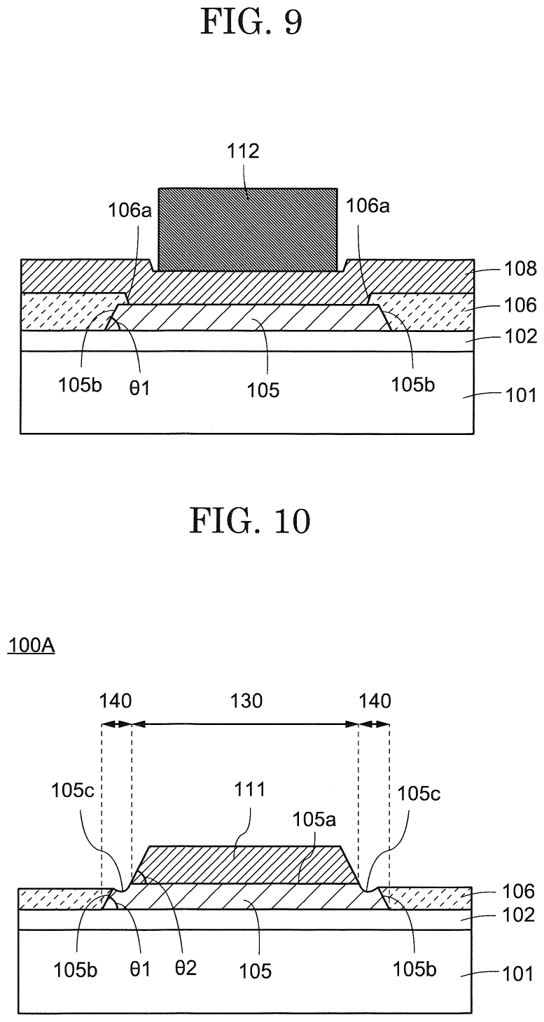

In the present embodiment, a laminated structure 100A having a structure partially different from that of the laminated structure 100 in the first embodiment will be described with reference to FIG. 9 and FIG. 10. In the laminated structure 100A, the shape of the insulating layer 106 in contact with the orientation pattern 105 is different from the shape of the insulating layer 106 in the laminated structure 100.

A method for manufacturing the laminated structure 100A in the present embodiment is the same as the method for manufacturing the laminated structure 100 in FIG. 1 to FIG. 5. The method for manufacturing the laminated structure 100A is different from the method for manufacturing the laminated structure 100 in that a region where a resist mask 112 is formed on the deposited semiconductor layer 108 is included.

As shown in FIG. 9, the resist mask 112 is formed inside the opening 106a of the insulating layer 106. Next, the insulating layer 106 is etched using the resist mask 112 to form the semiconductor pattern 111. In the present embodiment, the semiconductor layer 108 is etched by dry etching using a halogenated gas. With respect to the taper angle θ2, see the description of FIG. 6.

In the present embodiment, the resist mask 112 is arranged inside the opening 106a of the insulating layer 106. Therefore, when forming the semiconductor pattern 111 by etching, the top surface of the insulating layer 106 and the top surface 105a of the orientation pattern 105 are removed. In this case, the insulating layer 106 is in contact with the side surface 105b (also referred to as the outer peripheral side surface) of the orientation pattern 105, and is not in contact with the top surface 105a of the orientation pattern 105. In addition, the orientation pattern 105 has a first region 130 that overlaps the semiconductor pattern 111 and a second region 140 that does not overlap the semiconductor pattern 111. The orientation pattern 105 has a recess portion 105c near the bottom end of the semiconductor pattern 111 in the second region 140.

As shown in FIG. 10, the semiconductor pattern 111 does not overlap the insulating layer 106. Therefore, when the semiconductor layer 108 is deposited, even if there is a region having poor crystallinity in the region overlapping the insulating layer 106, it can be removed at the time of forming the semiconductor pattern 111. As a result, a semiconductor device can be manufactured using a highly crystalline semiconductor pattern.

### Third Embodiment

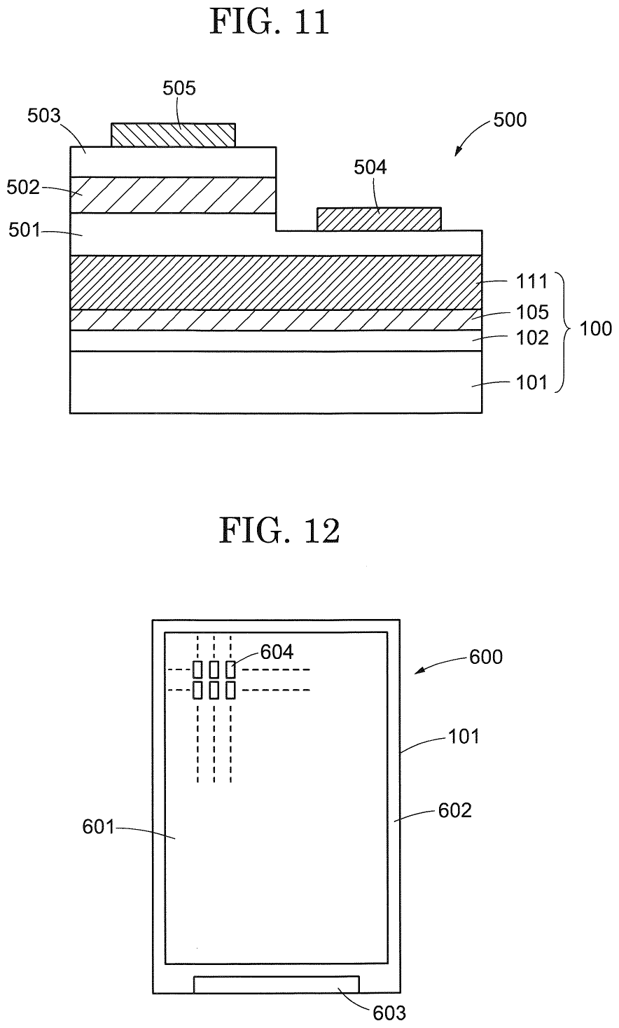

In the present embodiment, a semiconductor device 500 using the laminated structure 100 according to the first embodiment will be described with reference to FIG. 11 to FIG. 12.

FIG. 11 is an end view showing the semiconductor device 500 including the laminated structure 100 according to the first embodiment. Specifically, the semiconductor device 500 shown in FIG. 11 is an example of an LED element manufactured using the semiconductor pattern 111 shown in FIG. 4. In the drawing, the same elements as those of the laminated structure 100 shown in the first embodiment are denoted by the same reference signs, and redundant explanations are omitted.

As shown in FIG. 11, the semiconductor device 500 includes the laminated structure 100 in the first embodiment, an n-type gallium nitride layer 501 arranged on the semiconductor pattern of the laminated structure 100, an n-type electrode 504 arranged on the n-type gallium nitride layer 501, a light-emitting layer 502 spaced apart from the n-type electrode 504 and arranged on the n-type gallium nitride layer 501, a p-type gallium nitride layer 503 arranged on the light-emitting layer 502, and a p-type electrode 505 arranged on the p-type gallium nitride layer 503.

The semiconductor device 500 is formed by the process described below. After the semiconductor pattern 111 shown in FIG. 4 is formed, the n-type gallium nitride layer 501, the light-emitting layer 502, and the p-type gallium nitride layer 503 are sequentially grown on the semiconductor pattern 111. Thereafter, parts of the n-type gallium nitride layer 501, the light-emitting layer 502, and the p-type gallium nitride layer 503 are removed so that the n-type gallium nitride layer 501 is exposed. Finally, the n-type electrode 504 and the p-type electrode 505 are formed in contact with the n-type gallium nitride layer 501 and the p-type gallium nitride layer 503, respectively. With respect to the method for forming the n-type gallium nitride layer 501 and the p-type gallium nitride layer 503, the description of the n-type conductive semiconductor layer 108 and the p-type conductive semiconductor layer 108 in the first embodiment may be referred to.

Through the above process, the semiconductor device 500 shown in FIG. 11 is completed. The semiconductor device 500 of the present embodiment is formed using the highly crystalline semiconductor pattern 111 formed on the amorphous substrate 101. Therefore, according to the present embodiment, the semiconductor device 500 can be manufactured on the inexpensive amorphous substrate 101. In addition, since the semiconductor device 500 can be manufactured on the large-area amorphous substrate 101, productivity is improved. In addition, according to the present embodiment, since the highly crystalline gallium nitride layer can be formed by the sputtering method, the semiconductor device 500 can be manufactured with high throughput without being exposed to a high temperature throughout the entire process. Further, according to the present embodiment, a high-definition semiconductor device can be formed by using the laminated structure 100 having the fine semiconductor pattern 111.

The semiconductor device 500 shown in FIG. 11 is merely an example of an LED element and may be an LED element of another structure. For example, the light-emitting layer 502 may have a quantum-well structure in which the gallium nitride layer and the indium gallium nitride layer are alternately stacked.

In addition, although the example in which the semiconductor device 500 is manufactured using the laminated structure 100 has been described in the present embodiment, the semiconductor device 500 may be manufactured using the laminated structure 100A.

FIG. 12 is a plan view showing a light-emitting device 600 using the semiconductor device 500 including the laminated structure 100 according to the first embodiment. As shown in FIG. 12, a display unit 601 and a peripheral circuitry 602 are arranged on the amorphous substrate 101. A terminal 603 for inputting various signals (video signals and control signals) to the light-emitting device 600 is arranged in part of the peripheral circuitry 602. A plurality of pixels 604 is arranged in a matrix inside the display unit 601. The semiconductor device 500 shown in FIG. 11 is arranged in each pixel 604. Although not shown, a semiconductor chip for controlling light emission and non-light emission of the semiconductor device 500 may be arranged in each pixel 604.

### Fourth Embodiment

In the present embodiment, an example in which a semiconductor device is formed having a structure different from that of the second embodiment will be described. Specifically, in the present embodiment, an example in which a HEMT (High Electron Mobility Transistor) is formed as a semiconductor device will be described. In the drawing, the same elements as those of the laminated structure 100 shown in the first embodiment are denoted by the same reference signs, and redundant explanations are omitted.

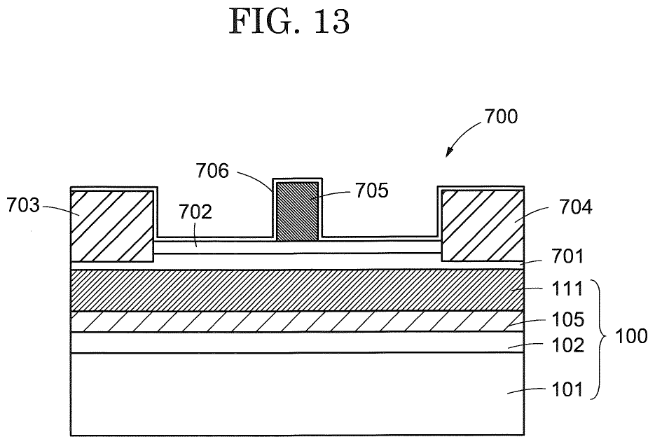

FIG. 13 is an end view showing a semiconductor device 700 including a gallium nitride-based semiconductor layer according to the fourth embodiment. Specifically, the semiconductor device 700 shown in FIG. 13 is an example of the HEMT manufactured using the semiconductor pattern 111 shown in FIG. 4 in the first embodiment.

As shown in FIG. 13, the semiconductor device 700 includes the laminated structure 100 in the first embodiment, an n-type aluminum gallium nitride layer 701 arranged on the semiconductor pattern of the laminated structure, an n-type gallium nitride layer 702 arranged on the n-type aluminum gallium nitride layer 701, a source electrode 703 arranged in contact with the n-type gallium nitride layer 702, a drain electrode 704 spaced apart from the source electrode 703 and in contact with the n-type aluminum gallium nitride layer 701, and a gate electrode 705 sandwiched between the source electrode 703 and the drain electrode 704 on the n-type aluminum gallium nitride layer 701. In the semiconductor device 700, silicon nitride may be arranged as a protective layer on the source electrode 703, the drain electrode 704, and the gate electrode 705.

The semiconductor device 700 is formed by the process described below. The n-type aluminum gallium nitride layer 701 and the n-type gallium nitride layer 702 are sequentially formed on the semiconductor pattern 111 made of the gallium nitride-based semiconductor layer. The sputtering method can be used to form these gallium nitride-based semiconductor layers. A trench reaching the n-type aluminum gallium nitride layer 701 is arranged in the n-type aluminum gallium nitride layer 701 and the n-type gallium nitride layer 702, and the source electrode 703 and the drain electrode 704 are arranged therein. The gate electrode 705 in contact with the n-type gallium nitride layer 702 is arranged between the source electrode 703 and the drain electrode 704. Finally, a silicon nitride layer 706 is formed as a protective layer, thereby completing the HEMT shown in FIG. 13.

The semiconductor device 700 of the present embodiment is formed using the highly crystalline gallium nitride layer (the semiconductor pattern 111) formed on the amorphous substrate 101. Therefore, according to the present embodiment, the semiconductor device 700 can be manufactured on the inexpensive amorphous substrate 101. In addition, since the semiconductor device 500 can be manufactured on the large-area amorphous substrate 101, productivity is improved. In addition, according to the present embodiment, since a plurality of gallium nitride-based semiconductor layers is formed by a sputtering method, the semiconductor device 700 can be manufactured with high throughput without being exposed to high temperature throughout the entire process. Furthermore, according to the present embodiment, a high-definition semiconductor device can be formed by using the laminated structure 100 having the fine semiconductor pattern 111. In addition, the semiconductor device 700 shown in FIG. 13 is merely an example of the HEMT, and may be the HEMT of another structure.

Each of the embodiments described above as an embodiment of the present invention can be appropriately combined and implemented as long as no contradiction is caused. The addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A laminated structure comprising:
an amorphous substrate having an insulating surface;
an orientation pattern on the amorphous substrate;
an insulating layer in contact with a side surface of the orientation pattern and surrounding the periphery of the orientation pattern; and
a semiconductor pattern containing gallium nitride on the orientation pattern,
wherein
the insulating layer has a first region overlapping the semiconductor pattern and a second region not overlapping the semiconductor pattern.

2. The laminated structure according to claim 1, wherein
a top surface of the second region is positioned lower than a top surface of the first region.

3. The laminated structure according to claim 2, wherein
the insulating layer has a side surface that is contiguous with the top surface of the first region in the second region.

4. A laminated structure comprising:
an amorphous substrate having an insulating surface;
an orientation pattern on the amorphous substrate;
an insulating layer in contact with an outer peripheral side surface of the orientation pattern and not contacting with the top surface of the orientation pattern; and
a semiconductor pattern containing gallium nitride on the orientation pattern,
wherein the orientation pattern has a first region overlapping the semiconductor pattern and a second region not overlapping the semiconductor pattern.

5. The laminated structure according to claim 4, wherein
the orientation pattern has a recess portion near the bottom end of the semiconductor pattern in the second region.

6. The laminated structure according to claim 1, wherein
the orientation pattern is composed of a conductive material or insulating material having a c-axis orientation.

7. The laminated structure according to claim 1, wherein
the amorphous substrate is an amorphous glass substrate or a resin substrate.

8. A method for manufacturing a laminated structure comprising:
forming an orientation layer on an amorphous substrate having an insulating surface;
forming an orientation pattern on the insulating surface by etching the orientation layer;
depositing an insulating layer on the insulating surface and the orientation pattern;
forming the insulating layer so as to contact with a side surface of the orientation pattern and to surround the periphery of the orientation pattern by etching the insulating layer;
depositing a semiconductor layer containing gallium nitride on the insulating layer and the orientation pattern; and
forming a semiconductor pattern on a top surface of the orientation pattern by etching the semiconductor layer containing gallium nitride,
wherein
the insulating layer surrounding the periphery of the orientation pattern has a first region overlapping the semiconductor pattern and a second region not overlapping the semiconductor pattern.

9. The method according to claim 8, wherein
the insulating layer is deposited so that the thickness of the insulating layer is substantially the same as the thickness of the orientation pattern.

10. The method according to claim 8, wherein
the semiconductor layer is etched so that the top surface of the second region in the orientation layer is positioned lower that the top surface of the first region.

11. The method according to claim 8, wherein
in the insulating layer surrounding the periphery of the orientation pattern, the semiconductor layer is etched so that a side surface contiguous with the top surface is formed in the second region.

12. The method according to claim 8, wherein
the semiconductor layer is etched so that the orientation pattern has a recess portion near the bottom end of the semiconductor pattern.

13. The method according to claim 8, wherein
the orientation pattern is composed of a conductive material or insulating material having a c-axis orientation.

14. The method according to claim 8, wherein
the amorphous substrate is an amorphous glass substrate or a resin substrate.

15. The method according to claim 8, wherein
the semiconductor layer containing gallium nitride is formed by a sputtering method.

16. A semiconductor device using the laminated structure according to claim 1.
